(19) United States
(12) Patent Application Publication
(10) Pub. No.: US 2013/0313604 A1
(43) Pub. Date: Nov. 28, 2013

(54) Method for Producing a Light-Emitting Semiconductor Component and Light-Emitting Semiconductor Component

(71) Applicants: Karl Engl, Pentling (DE); Richard Baisl, Regensburg (DE); Tilman Schlenker, Nittendorf (DE); Lutz Hoeppel, Alteglofsheim (DE); Sebastian Taeger, Regensburg (DE); Christian Gaertner, Regensburg (DE)

(72) Inventors: Karl Engl, Pentling (DE); Richard Baisl, Regensburg (DE); Tilman Schlenker, Nittendorf (DE); Lutz Hoeppel, Alteglofsheim (DE); Sebastian Taeger, Regensburg (DE); Christian Gaertner, Regensburg (DE)

(73) Assignee: OSRAM OPTO SEMICONDUCTORS GmbH, Regensburg (DE)

(21) Appl. No.: 13/991,135

(22) PCT Filed: Apr. 11, 2012
(86) PCT No.: PCT/EP2012/056536

§ 371 Date: Aug. 14, 2013

(30) Foreign Application Priority Data
Apr. 13, 2011 (DE) 10 2011 016 935.0

(51) Int. Cl. H01L 33/52; H01L 33/60

(52) U.S. Cl. CPC H01L 33/52; H01L 33/60
USPC 257/98; 438/27

(57) ABSTRACT

A method for producing a light-emitting semiconductor component is specified. A light-emitting semiconductor chip is arranged on a mounting area of a carrier. The semiconductor chip is electrically connected to electrical contact regions on the mounting area. An encapsulation layer is applied to the semiconductor chip by means of atomic layer deposition. All surfaces of the semiconductor chip which are free after mounting and electrical connection are covered with an encapsulation layer. Furthermore, a light-emitting semiconductor component is specified.

This patent application is a national phase filing under section 371 of PCT/EP2012/056536, filed Apr. 11, 2012, which claims the priority of German patent application 10 2011 016 935.0, filed Apr. 13, 2011, each of which is incorporated herein by reference in its entirety.

### TECHNICAL FIELD

A method for producing a light-emitting semiconductor component and a light-emitting semiconductor component are specified.

### BACKGROUND

It is known to incorporate light-emitting diode chips in housings or on carriers in order to produce so-called LED packages (LED: light-emitting diode). In such packages, however, the light-emitting diode chips are not completely protected against harmful substances such as, for instance, moisture or in an environment comprising corrosive or otherwise harmful substances such as, for instance, H₂S, SO₂ and chlorine. This is owing to the fact, inter alia, that potting materials composed of silicone or some other resin are usually used, which have a certain moisture permeability that cannot be prevented. Therefore, in the case of known packages, light-emitting diode chips and for example also conductor tracks in the package have to satisfy minimum requirements with regard to moisture stability and stability in harmful environments. These requirements have the effect, inter alia, that chip design and packages cannot be optimized for maximum efficiency, because for example light-absorbing moisture barriers have to be incorporated in the light-emitting diode chips and/or in the package for example highly reflective leadframe materials sensitive to moisture or other harmful substances can be used only to a limited extent or even cannot be used at all.

### SUMMARY OF THE INVENTION

Certain embodiments specify a method for producing a light-emitting semiconductor component. Further embodiments specify a light-emitting semiconductor component.

In accordance with at least one embodiment, a method for producing a light-emitting semiconductor component comprises a method step in which a carrier is provided. The carrier can comprise a plastic material and/or particularly preferably a ceramic material. In one particularly preferred embodiment, the carrier is embodied as a ceramic carrier.

In accordance with a further embodiment, the carrier has a mounting area provided for enabling a light-emitting semiconductor chip to be mounted and electrically connected thereon. For this purpose the mounting area can have at least one electrical contact region or else a plurality of contact regions, to which the light-emitting semiconductor chip can be connected by means of an electrically conductive connecting material. The mounting area and, in particular, the at least one or the plurality of electrical contact regions can be provided for enabling the semiconductor chip to be mounted and/or connected by means of an electrically conductive connecting material, as explained further below.

In accordance with a further embodiment, the carrier has at least one and preferably a plurality of electrical connection regions, by means of which the semiconductor component can be connected to an external current and/or voltage source. The at least one or the plurality of connection regions can preferably be connected to the at least one or the plurality of contact regions via at least one or a plurality of electrically conductive connections. The electrically conductive connections and furthermore also the contact regions and the connection regions can be formed, for example, by parts of a leadframe and/or by conductor tracks, parts thereof and/or contact layers which are arranged on the mounting area or at least partly also in the carrier.

In accordance with a further embodiment, the carrier has a reflective layer, in particular a mirror layer, which is arranged on at least one part of the mounting area. By way of example, the minor layer can cover a part of a conductor track. It is also possible for at least one part of a conductive track to be embodied as a mirror layer. Furthermore, the minor layer can additionally or alternatively be arranged on a part of one or a plurality of contact regions, on at least one contact region, in a manner surrounding a contact region, below a semiconductor chip mounted on the carrier, alongside a semiconductor chip mounted on the carrier, or a combination thereof. The minor layer can be arranged in particular in regions of the mounting area onto which light from a light-emitting semiconductor chip arranged on the mounting area can be radiated. Particularly advantageously, the mirror layer can be arranged on those regions which can at least partly absorb the light emitted by the semiconductor chip. As a result, an increase in the coupling out efficiency or the emission intensity can be achieved by means of the mirror layer.

In accordance with a further embodiment, the mirror layer comprises silver. By way of example, the minor layer can comprise or be a silver layer or a silver-containing layer. Furthermore, the minor layer can comprise, for example, at least one transparent dielectric layer, for example, composed of silicon oxide. Furthermore, the minor layer can also comprise a plurality of transparent dielectric layers that form a Bragg mirror. It is also possible for the minor layer to have Bragg-like construction comprising a silver layer, on which at least one transparent dielectric layer, for example, a silicon oxide layer, in particular a silicon dioxide layer, is applied. That can mean, in particular, that the minor layer comprises or is composed of a silver layer and thereabove a vitreous coating composed, for example, of silicon dioxide.

In accordance with a further embodiment, at least one light-emitting semiconductor chip is provided. The light-emitting semiconductor chip can be embodied in particular as a light-emitting diode chip, edge-emitting semiconductor laser, vertically emitting semiconductor laser (VCSEL), as a light-emitting diode chip array, as a laser array or as a plurality or combination thereof. For this purpose, the semiconductor chip can comprise one or a plurality of functional semiconductor layer sequences, for example, selected from the material groups AlGaAs, InGaAlP, AlInGaN or from a II-VI compound semiconductor system or some other semiconductor material. The semiconductor layer sequence can have at least one active, light-emitting region such as, for instance, a pn junction, a double heterostructure, a single quantum well structure (SQW structure), or a multi-quantum well structure (MQW structure), and have electrical contact structures such as, for instance, metal layers, electrode layers and/or electrical feedthroughs.

By way of example, electrode layers can be arranged on different sides of the active, light-emitting region or of the semiconductor layer sequence. Furthermore, at least one of the electrical contact structures can also be embodied in the form of plated-through holes which project from one side of the semiconductor layer sequence through the active light-emitting region to the other side, such that the light-emitting region of the semiconductor layer sequence can be connected on both sides from the same side of the semiconductor layer sequence.

Furthermore, the light-emitting semiconductor chip can also be embodied as a thin-film light-emitting diode chip. A thin-film light-emitting diode chip is distinguished in particular by the following characteristic features:
a reflective layer is applied or formed at a first main area—facing toward a carrier element—of a radiation-generating epitaxial layer sequence, said reflective layer reflecting at least part of the electromagnetic radiation generated in the epitaxial layer sequence back into the latter;
the epitaxial layer sequence has a thickness in the range of 20 μm or less, in particular in the range of 10 μm; and
the epitaxial layer sequence contains at least one semiconductor layer having at least one area having an intermixing structure which ideally leads to an approximately ergodic distribution of the light in the epitaxial layer sequence, that is to say that it has an as far as possible ergodically stochastic scattering behavior.

A basic principle of a thin-film light-emitting diode chip is described, for example, in I. Schnitzer et al., Appl. Phys. Lett. 63 (16), 18 Oct. 1993, 2174-2176, the disclosure content of which in this respect is hereby incorporated by reference.

In accordance with a further embodiment, at least one light-emitting semiconductor chip is arranged on the mounting area of the carrier and mounted on said mounting area. The mounting of the semiconductor chip can be effected, for example, by means of adhesive bonding, that is to say by means of an electrically conductive adhesive, for example, by means of an anisotropically electrically conductive adhesive. Alternatively or additionally, the mounting of the semiconductor chip can also be effected by means of a solder. Particularly preferably, the mounting of the semiconductor chip on the mounting area can be effected by means of a sintering connection. For this purpose, a sinterable material in the form of a powder or granules is provided as connecting material, which furthermore can for example also comprise sintering aids and binders. The sintering material, which can particularly preferably comprise silver, that is to say, for example, a silver powder or granules, is applied to the mounting area and/or a mounting region of the semiconductor chip. The light-emitting semiconductor chip is arranged on the sintering material or with the sintering material on the mounting area of the carrier. The sintering material can be sintered by the action of heat and/or by laser fusion, thereby producing a sintering connection, which can have a porous structure. The sintering connection can be distinguished in particular by a high thermal conductivity and good electrical conductivity.

In accordance with a further embodiment, the light-emitting semiconductor chip is electrically connected on the carrier. The electrical connection of the semiconductor chip can be effected, for example, by one of the abovementioned mounting methods or one of the abovementioned mounting steps. For this purpose, the semiconductor chip can be applied and mounted directly on a contact region of the carrier. Furthermore, the electrical connection of the light-emitting semiconductor chip at least to an electrical contact region of the carrier can be effected by means of a wire connection, in particular a bonding wire connection. For electrically connecting the semiconductor chip by means of a wire connection, preferably a contact region on the carrier is arranged alongside the semiconductor chip.

In accordance with a further embodiment, an encapsulation layer is applied on free surfaces of the semiconductor chip. In this case, free surfaces denote those surfaces which are not covered by any material after the mounting and electrical connection of the semiconductor chip. In particular, the encapsulation layer can be applied in such a way that all surfaces of the semiconductor chip which are free after mounting and electrical connection are completely covered with the encapsulation layer. In this case, the encapsulation layer can cover the entire semiconductor chip, such that the semiconductor chip is enclosed by the encapsulation layer and the carrier.

In accordance with a further embodiment, the encapsulation layer is additionally arranged on regions of the mounting area. These regions can be arranged in particular adjacent to the semiconductor chip and can adjoin the semiconductor chip. As a result, it is possible to produce a closed encapsulation layer which extends from regions of the mounting area over the semiconductor chip, in particular at least over all free surfaces of the semiconductor chip, and can therefore ensure, together with the carrier, that the semiconductor chip is encapsulated on all sides. Particularly preferably, the encapsulation layer can also be applied on those regions of the mounting area which are sensitive to harmful substances, that is to say, for example, moisture, air, oxygen, hydrogen sulfide (H₂S), sulfur dioxide (SO₂) and/or chlorine. Such sensitive regions can be formed, for example, by an abovementioned minor layer and/or by regions of conductor tracks.

In accordance with a further embodiment, the encapsulation layer is applied on all free surfaces of the semiconductor chip and on the entire mounting area apart from the connection regions. For this purpose, the encapsulation layer can also additionally be applied on the connection regions, which can subsequently be uncovered again for example by means of a dry-chemical plasma method. If the electrical connection of the semiconductor chip is effected by means of at least one bonding wire or a wire connection, then the encapsulation layer can also be applied on and in particular around the bonding wire and concomitantly encapsulate the latter together with the semiconductor chip.

By means of the encapsulation layer, the semiconductor chip or the semiconductor chip and those regions of the carrier which are covered by the encapsulation layer can be hermetically impermeably covered and thereby sealed and encapsulated. That can mean that harmful substances, for example, moisture, air, oxygen, hydrogen sulfide (H₂S), sulfur dioxide (SO₂) and chlorine, cannot penetrate through the encapsulation layer or can penetrate through said encapsulation layer only to such a small extent that the semiconductor component is not significantly impaired. “Hermetically impermeably” can denote, in particular, an encapsulation layer having a permeability to harmful substances that is so low that as a result of the entry of harmful substances as calculated over the lifetime of the component, the risk of failure and/or damage to the component can be reduced or completely prevented.

In accordance with a further embodiment, the encapsulation layer has a permeability to water vapor (WVTR: “water vapor transmission rate”) of less than 10⁻⁵ g/m²/day. Such an encapsulation layer can make it possible to prevent, or at least considerably reduce in comparison with known LED packages, a penetration of harmful substances, in particular of moisture, to the sensitive regions of the semiconductor component, in particular to the semiconductor chip and, if appropriate, to further structural parts or elements such as, for example, the minor layer and/or conductor tracks and/or an abovementioned sintering connection between the semiconductor chip and the carrier.

In accordance with a further embodiment, the encapsulation layer is applied by means of atomic layer deposition. In the method of atomic layer deposition (ALD), formation of a layer composed of an encapsulation material on a surface or a surface region of the semiconductor component, in particular at least the free surfaces of the semiconductor chip, is made possible by a chemical reaction of at least two starting substances or compounds (“precursor”) provided in gaseous form. In comparison with other methods of chemical vapor deposition, in the case of atomic layer deposition, the starting compounds are admitted cyclically successively into a reaction chamber. A first of the at least two gaseous starting compounds can adsorb on the surface to be coated, wherein the molecules of the first starting compound arrange themselves irregularly and without a long-range order on the surface region and can thus form an at least partly amorphous covering. After a preferably complete or almost complete covering of the surface with the first starting compound, a second of the at least two starting compounds can be supplied, which reacts with the first starting compound adsorbed surface to be coated, as a result of which a sub-monolayer or maximally a monolayer of the encapsulation material can be formed. Further sub-monolayers or monolayers can be produced by repeating these steps. One essential feature of atomic layer deposition is the self-limiting character of the partial reaction, which means that the starting compound of a partial reaction does not react with itself or ligands of itself, which limits the layer growth of a partial reaction, even with an arbitrary period of time and gas quantity, to maximally a monolayer of the sealing material on the at least one surface region. Depending on method parameters and reaction chamber and also depending on the encapsulation material or the starting compounds thereof, a cycle can last between a few milliseconds and a few seconds, in which case a layer composed of the sealing material having a thickness of approximately 0.1 to approximately 3 angstroms can then be produced per cycle.

Besides atomic layer deposition, the method of molecular layer deposition (MLD) can alternatively or additionally also be carried out, wherein corresponding molecular layers are deposited instead of atomic monolayers or sub-monolayers in the individual method steps. By way of example, organic materials can thereby be deposited layer by layer. It is also possible to combine the initial products of ALD and MLD in order thus to produce inorganic-organic hybrid layers, for example.

In accordance with a further embodiment, the encapsulation layer is applied with a thickness of greater than or equal to 10 nm. Even with this thickness, encapsulation materials applied by means of atomic layer deposition can already have a high barrier effect with respect to harmful substances. In particular, the encapsulation layer having such a thickness can be free of pores, such that there are no permeation paths for harmful substances between the environment of the light-emitting semiconductor component and, for example, the semiconductor chip. By virtue of the fact that the encapsulation layer is applied only after the mounting and electrical connection of the at least one semiconductor chip, the encapsulation layer can be applied independently of the method for producing the semiconductor chip, in particular, for example, also of singulation and/or handling steps, by which the encapsulation layer would otherwise possibly be damaged and broken up at points. On account of the freedom from pores and the high density of the encapsulation layer, the latter can have a thickness of less than 100 nm. The smaller the thickness of the encapsulation layer, the lower the outlay in terms of time and material for production, as a result of which a high economic viability can arise. The thicker the encapsulation layer, the more resistant it can be, for example, to mechanical impairments and the greater can be the durability of the hermetic encapsulation property of the encapsulation layer. In particular, by means of the atomic layer deposition method, the encapsulation layer can also be applied uniformly and without pores even on regions that are difficult to access and also on geometrical elevations and depressions such as, for instance, openings, steps and edges.

In accordance with a further embodiment, the encapsulation layer is electrically insulating and optically transparent and can comprise, for example, an oxide, nitride or oxynitride, for example, comprising one or a plurality of materials selected from aluminum, silicon, titanium, zirconium, tantalum and hafnium. The encapsulation layer can preferably comprise one or a plurality of layers formed by one or a plurality of the following materials: Al₂O₃, ZrO₂, TiO₂, Ta₂O₅, SiO₂, Si₃N₄, HFO₂, ZnSnOₓ. Examples of suitable starting compounds include organometallic compounds or hydrides of the stated materials and also, for example, ammonia, nitrous oxide or water as starting compound for oxygen or nitrogen. The one or the totality of the plurality of layers of the encapsulation layer can in this case have a thickness of less than 100 nm.

In accordance with a further embodiment, a wavelength conversion element is applied on the semiconductor chip. In this case, the wavelength conversion element can be arranged on the semiconductor chip before the encapsulation layer is applied. As an alternative thereto or in addition, a wavelength conversion element can be arranged or applied after the encapsulation layer has been applied, that is to say on the encapsulation layer above the semiconductor chip. If the wavelength conversion element is arranged between the semiconductor chip and the encapsulation layer, then that may have the advantage that moisture-sensitive materials or those materials which are sensitive to other harmful substances can also be used as materials for the wavelength conversion element. If the wavelength conversion element is arranged above the encapsulation layer, then what can be achieved by the abovementioned small thickness of the encapsulation layer and the transparency thereof is that no optical impediment and thus reduction of efficiency is brought about by the encapsulation layer between the wavelength conversion element and the semiconductor chip.

In accordance with a further embodiment, the wavelength conversion element comprises a wavelength conversion substance. In this case, the wavelength conversion substance can comprise one or a plurality of the following materials: garnets of the rare earths and of the alkaline earth metals, for example, YAG:Ce³⁺, nitrides, nitridosilicates, sions, sialons, aluminates, oxides, halophosphates, orthosilicates, sulfides, vanadates and chlorosilicates. Furthermore, the wavelength conversion substance can additionally or alternatively comprise an organic material, which can be selected from the group comprising perylenes, benzopyrenes, coumarins, rhodamines and azo dyes. The wavelength conversion element can comprise suitable mixtures and/or combinations of the wavelength conversion substances mentioned.

In particular, the wavelength conversion element can be embodied as a ceramic lamina comprising a ceramic wavelength conversion substance. As an alternative thereto, the wavelength conversion element can also be arranged electrophoretically on or above the semiconductor chip or the encapsulation layer. For this purpose, a suitable wavelength conversion substance can be deposited electrophoretically. Furthermore, the wavelength conversion element can also comprise a plastic matrix in which a wavelength conversion substance is embedded or to which the wavelength conversion substance is bound. The transparent matrix material can comprise for example siloxanes, epoxides, acrylates, methyl methacrylates, imides, carbonates, olefins, styrenes, urethanes or derivatives thereof in the form of monomers, oligomers or polymers and furthermore also mixtures, copolymers or compounds comprising them. By way of example, the matrix material can comprise or be an epoxy resin, polymethyl methacrylate (PMMA), polystyrene, polycarbonate, polyacrylate, polyurethane or a silicone resin such as, for instance, polysiloxane or mixtures thereof.

In accordance with a further embodiment, an optical element is arranged above the semiconductor chip. In this case, the optical element can be arranged in particular on the encapsulation layer. In particular, the optical element can be embodied as a solid lens that is to say, for example, as an already prefabricated glass or plastic lens. As an alternative thereto, the lens can also be arranged above the semiconductor chip by applying (dispensing) a liquid material, for example, by applying dropwise or spraying, in particular, for example, a liquid resin such as, for instance, silicone.

In accordance with a further embodiment, further electrical and/or optoelectronic components are applied on the carrier and in particular, for example, on the mounting area. They can be applied on the carrier, and mounted and electrically connected thereon, in particular before the encapsulation layer is applied. The encapsulation layer can cover the further components. By way of example, at least one protective diode against electrostatic discharges (ESD) can be applied. Alternatively or additionally, it is also possible to apply one or a plurality of sensors or sensor elements, for example, temperature or light sensors, and alternatively or additionally further active and/or passive electronic components. By virtue of the fact that the further components can be arranged below the encapsulation layer and thus be protected by the encapsulation layer, they can be used regardless of their sensitivity to harmful substances. The further components can be arranged, for example, below an optical element or else on regions of the carrier alongside an optical element.

In accordance with a further embodiment, a protective layer is applied on the encapsulation layer. The protective layer can comprise one or a plurality of the materials mentioned in connection with the encapsulation layer. The protective layer can be applied by means of a chemical or physical vapor deposition method (PVD: “physical vapor deposition,” CVD: “chemical vapor deposition”). In particular, the protective layer can be applied, for example, by means of a plasma enhanced chemical vapor deposition method (PECVD). By means of such methods, protective layers can be grown rapidly with a high mechanical stability, such that a sufficiently high thickness can be produced economically.

Alternatively or additionally, the protective layer can also comprise an organic material, for example, a resin, and in particular parylene. Here and hereinafter, the term parylene denotes a group of thermoplastic polymers which comprise phenylene radicals linked via ethylene bridges in the 1,4-position and which can, for example, also be designated as poly-para-xylylene. In this case, hydrogen atoms can also be at least partly or wholly substituted by halogens, for example, by chlorine and/or fluorine atoms. Parylene of this type can have high thermal stability, that is to say does not degrade mechanically and/or optically at high temperatures, with the result that the light-emitting semiconductor component can be processed further even at high temperatures, for instance, during possible subsequent soldering processes. A protective layer composed of parylene can have a high layer thickness homogeneity and high adhesion to the encapsulation layer. Parylene can in particular also be distinguished by the fact that it can be highly transparent up to thicknesses of approximately 500 nm and in particular up to 400 nm.

In accordance with a further embodiment, the protective layer has a thickness of greater than 100 nm. In order to afford sufficient mechanical protection, the protective layer can have in particular a thickness of up to 5 μm, depending on material. In this case, the protective layer can have a permeability to harmful substances which is lower than that specified above for the encapsulation layer and is more than 10⁻⁴ g/m²/day, for example, for moisture, since the encapsulation effect can already be ensured by the encapsulation layer. Therefore the protective layer, in particular its thickness and material, can be selected just for ensuring mechanical protection.

In accordance with a further embodiment, a light-emitting semiconductor component comprises a carrier, on which a light-emitting semiconductor chip is mounted and electrically connected. An encapsulation layer is arranged above the semiconductor chip, in particular, above all free surfaces of the semiconductor chip, which encapsulation layer was applied by means of atomic layer deposition.

In accordance with a further embodiment, for the purpose of mounting the semiconductor chip, a connecting layer composed of a sintering material is arranged between the semiconductor chip and the mounting area of the carrier, particularly preferably in the case of the silver-containing sintering material.

The light-emitting semiconductor component can have further features described in conjunction with the method for producing the light-emitting semiconductor component.

In comparison with known packages comprising light-emitting diode chips, the semiconductor component described here can have an increased stability even in a moist environment or in an environment having other harmful substances, for example, outdoors since, by means of the encapsulation layer, the semiconductor chip and also the sensitive components such as, for instance, leadframes or conductor tracks, can be protected by the encapsulation layer. Furthermore, it may be possible that, in comparison with known packages, an increase in the efficiency of the emitted light can be achieved since, for example, silver can be used as material for a minor layer and/or for a leadframe and/or for conductor tracks, as a result of which an absorption of light can be considerably reduced in comparison with customary leadframe materials. The susceptibility of silver to migration in particular in a moist or other harmful environment can be prevented in this case by arrangement below the encapsulation layer. Consequently, the semiconductor component described here, in comparison with known packages, can have a generally increased durability and resistance to storage or operating conditions, even in a moist environment and/or in a salt-containing atmosphere and/or in a pollutant-gas-containing atmosphere, for example, a hydrogen sulfide atmosphere.

In comparison with known packages, the semiconductor component described here can have an increased design freedom in optimizing efficiency since known protective layers, which often absorb light, can be avoided, with the result that a higher luminous efficiency can be produced. Since the semiconductor chip is protected against the environment by the encapsulation layer, the chip design can be simplified, which makes it possible to avoid process costs and an increase in yield by reduction of yield-critical process steps which are necessary in the case of known packages in order to provide the chip with moisture barriers.

By applying the encapsulation layer, protection of the sensitive regions, for example, regions of the semiconductor chip and/or of the further sensitive materials, element and/or structural parts mentioned above, can be achieved in a single method step, as a result of which a cost saving can be brought about.

In comparison with known methods, adverse influences, for example, caused by processes such as laser separation for singulating light-emitting diode chips, can be minimized. Light-emitting diode chips are generally characterized a hundred percent in the wafer assemblage before the chips are singulated. Influences resulting from the separating process are not taken into account in this prior measurement. However, separating processes and handling of light-emitting diode chips can cause microscopic hairline cracks in an individual layer or passivation layers of the chips, which can lead to degradation or even to failure of components, because sensitive constituent parts are attacked, only as a result of relatively long operation in a corresponding, in particular moist, environment. Such microscopic damage cannot be detected, but can be effectively closed and thus rendered harmless by means of the encapsulation layer described herein.

### BRIEF DESCRIPTION OF THE DRAWINGS

Further advantages and advantageous embodiments will become apparent from the exemplary embodiments described below in conjunction with the figures.

FIGS. 1A to 1D show schematic plan views of method steps of a method for producing a semiconductor component in accordance with one exemplary embodiment;

FIG. 1E shows a schematic plan view of a further method step for producing semiconductor components in accordance with a further exemplary embodiment;

FIGS. 2A to 2C show schematic plan views of carriers for semiconductor components in accordance with further exemplary embodiments; and

FIGS. 3A and 3B show schematic sectional illustrations of semiconductor components in accordance with further exemplary embodiments.

In the exemplary embodiments and figures, identical or identically acting constituent parts may in each case be provided with the same reference signs. The elements illustrated and their size relationships among one another should not be regarded as true to scale, in principle; rather individual elements such as, for example, layers, structural parts, components and regions may be illustrated with exaggerated thickness or size dimensions in order to enable better illustration and/or in order to afford a better understanding.

### DETAILED DESCRIPTION OF ILLUSTRATIVE EMBODIMENTS

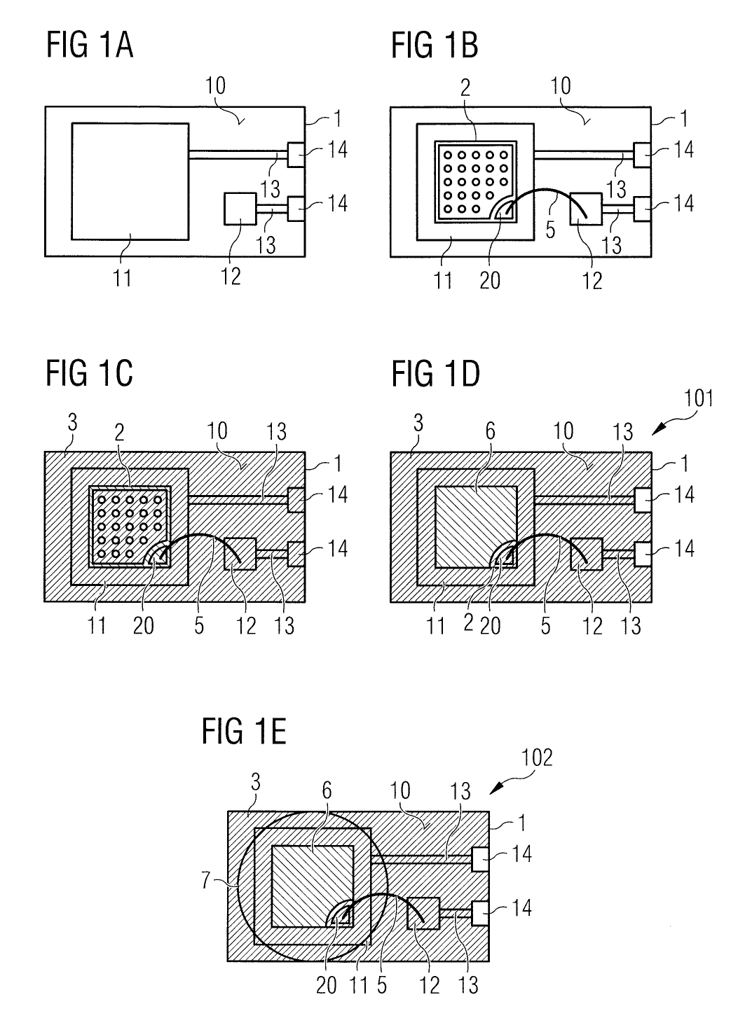

A method for producing a semiconductor component 101 in accordance with one exemplary embodiment is shown in conjunction with FIGS. 1A to 1D.

A first method stop in accordance with FIG. 1A involves providing a carrier 1, which has contact regions 11, 12 and also electrical connection regions 14 on a mounting area 10. The contact regions 11, 12 and pad regions 14 are connected to one another by means of conductor tracks 13 on the carrier 1. In particular, in the exemplary embodiment shown, the carrier 1 is embodied as a ceramic carrier, on which the contact regions 11, 12, the connection regions 14 and the conductor tracks 13 are embodied as a coating. The connection regions 14 are embodied as n- and p-type contacts.

In a further method step in accordance with FIG. 1B, a semiconductor chip 2 is provided and is mounted and electrically connected on the mounting area 10 of the carrier 1.

The semiconductor chip 2 is mounted and thus simultaneously electrically connected by means of a connecting material (not shown) on the contact region 11 on the mounting area 10. The connecting material is formed by an electrically conductive adhesive, a solder, or particularly preferably by an electrically conductive sintering material, in particular a silver-containing sintering material. For this purpose, on the side facing the carrier 1 the semiconductor chip 2 has a corresponding electrode layer or a corresponding contact structure. On that side of the semiconductor chip 2 that faces away from the carrier 1 a further electrode layer or a further electrical contact structure 20 is present, which is connected by means of a wire connection 5, formed by a bonding wire, to the contact region 12 on the mounting area 10 of the carrier 1. As an alternative thereto, it may also be possible for the semiconductor chip 2 to have both contact structures on the side facing the carrier 1 such that the semiconductor chip 2 is already completely electrically connected upon the mounting of the semiconductor chip 2.

In the exemplary embodiment shown, the light-emitting semiconductor chip 2 has a semiconductor layer sequence based on a nitride compound semiconductor material and having, in particular, an active, light-emitting region based on InGaN. As an alternative thereto, the light-emitting semiconductor chip 2 can have one or more features as described above in the general part.

In a further method step in accordance with FIG. 1C, an encapsulation layer 3 is applied on the surfaces of the semiconductor chip 2 which are free after mounting and electrical connection. Furthermore, in the same method step, the encapsulation layer 3 is also applied on the entire region of the mounting area 10 which is arranged alongside the semiconductor chip 2, such that the semiconductor chip 2 and the entire mounting area 10 including the bonding wire 5 are covered with the encapsulation layer 3.

The encapsulation layer 3 is applied by means of atomic layer deposition and, in the exemplary embodiment shown, has a layer sequence comprising one or a plurality of layers of aluminum oxide, zirconium oxide, titanium oxide, tantalum oxide, silicon dioxide and/or a combination thereof. In this case, the encapsulation layer 3 is applied with a thickness of greater than or equal to 10 nm and less than 100 nm and, on account of the atomic layer deposition method, covers all geometrical elevations and depressions on the mounting area 10 and the semiconductor chip 2 including the bonding wire 5. As a result, it is possible to achieve an encapsulation of the semiconductor chip 2 and also of the further regions of the carrier 1, and respectively of the mounting area 10, which has a permeability to moisture (WVTR) of less than 10⁻⁵ g/m²/day in the exemplary embodiment shown. As a result, the semiconductor component 101 produced in this way has the advantages described above in the general part.

As an alternative or in addition to the atomic layer deposition method, a molecular layer deposition can also be carried out.

In a further method step, shown in conjunction with FIG. 1D, the encapsulation layer 3 is cleaned from the connection regions 14. The removal of the encapsulation layer 3 from the connection regions 14 can be effected by means of a dry-chemical plasma method, for example.

In the exemplary embodiment shown, in order to complete the light-emitting semiconductor component 101, in a further method step, a wavelength conversion element 6 is applied above the semiconductor chip 2 on the encapsulation layer 3. As described in the general part, the wavelength conversion element 6 can be embodied, for example, as a ceramic lamina or as a plastic element with a wavelength conversion substance arranged therein, or else can be deposited electrophoretically. The wavelength conversion element 6 and the semiconductor chip 2 can be embodied, for example, in such a way that the light-emitting semiconductor component 101 can emit white light. Such combinations of semiconductor chips and wavelength conversion elements are known to the person skilled in the art and will not be explained in further detail here.

As an alternative thereto, the wavelength conversion element 6 can also be arranged on the semiconductor chip 2 before the step of applying the encapsulation layer 3 as shown in conjunction with FIG. 1C. Furthermore, it is also possible in this case for the wavelength conversion element 6 to be applied on the semiconductor chip 2 before the mounting thereof and the semiconductor chip 2 together with the wavelength conversion element 6 to be mounted on the carrier 1 in the method step shown in FIG. 1B. As an alternative thereto, it may also be possible that no wavelength conversion element 6 is arranged on the semiconductor chip 2.

Furthermore, above the encapsulation layer 3, it is also possible to apply a protective layer (not shown) in the form of one or a plurality of oxide, nitride or oxynitride layers by means of a PVD or CVD method with a thickness of greater than or equal to 100 nm and less than or equal to 5 μm, which can form mechanical protection of the light-emitting semiconductor component 101. It is also possible for parylene to be applied as protective layer, as described in the general part.

FIG. 1E shows a further method step for producing a light-emitting semiconductor component 102 in accordance with a further exemplary embodiment, wherein the semiconductor component is furthermore also provided with an optical element 7, in particular a lens. For this purpose an already prefabricated lens composed, for example, of glass or a plastic can be mounted on the encapsulation layer 3, above the semiconductor chip 2. As an alternative thereto, it is also possible for the optical element 7 in the form of a lens to be formed above the semiconductor chip 2 by means of applying (dispensing) a liquid material, in particular a silicone resin.

In addition, even further electrical, electronic and/or optoelectronic components can be arranged on the carrier 1, and in particular on the mounting area 10, in particular before the encapsulation layer 3 is applied. Said components can be for example one or a plurality of ESD protective diodes, a plurality of sensors, for example, light and/or temperature sensors, and/or one or a plurality of active and/or passive electronic components. By applying the encapsulation layer 3 above the further components, the latter can likewise be protected by the encapsulation layer 3.

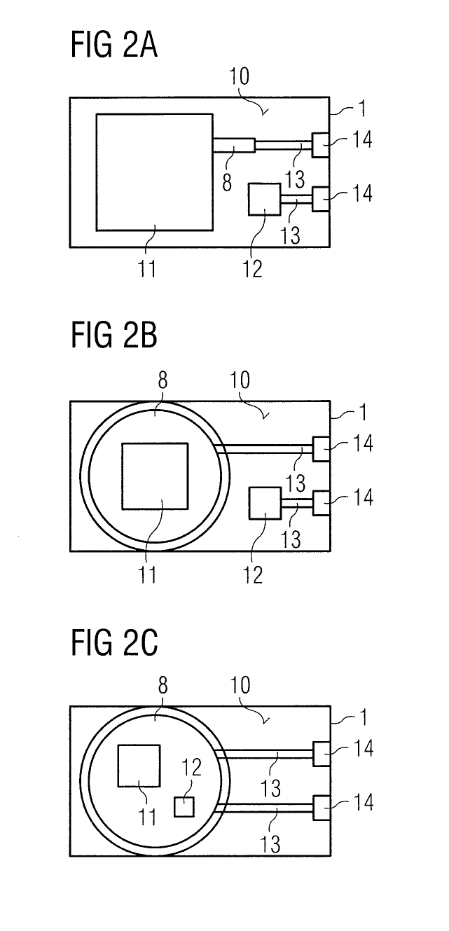

FIGS. 2A to 2C show carriers 1 for light-emitting semiconductor components in accordance with further exemplary embodiments, on which at least one light-emitting semiconductor chip 2 and also the encapsulation layer 3 and, if appropriate, also a wavelength conversion element 6 and/or an optical element 7 can be applied in accordance with the method described above.

The carrier 1 in FIG. 2A has a minor layer 8 in a coupling-out region, that is to say in a region onto which light is radiated by the semiconductor chip 2 during operation, on a conductor track 13, which mirror layer is composed of silver in the exemplary embodiment shown. By way of example, the conductor track 13 in this region can also be formed by the minor layer 8 composed of silver.

The carrier 1 in accordance with the exemplary embodiment in FIG. 2B has a minor layer 8 as a reflective support or as a reflective layer in the coupling-out region all around the contact region 11, on which the semiconductor chip 2 is mounted. Said layer can be formed by a silver layer, a Bragg minor or a Bragg-like layer having a silver layer in conjunction with a vitreous coating, for example, composed of silicon dioxide.

The carrier 1 in accordance with the exemplary embodiment in FIG. 2C has a minor layer 8 like the previous exemplary embodiment, both contact regions 11, 12 being arranged in the region surrounded by the mirror layer 8. In particular, the regions covered by the minor layer 8 in the exemplary embodiments in accordance with FIGS. 2B and 2C can correspond to that region of the carrier 1, or respectively of the mounting area 10, which is arranged below an optical element 7, that is to say a lens, for example, as indicated in FIGS. 2B and 2C by the depicted contour line of an exemplary optical element 7.

As a result of the encapsulation layer being applied, as described in conjunction with FIGS. 1A to 1D, in particular silver can be used as material for the minor layer 8 in accordance with the exemplary embodiments in FIGS. 2A to 2C since the high susceptibility of silver to migration in particular in a moist environment can no longer lead to the failure of the semiconductor components, since the minor layer 8 is enclosed and thus protected by the encapsulation layer 3.

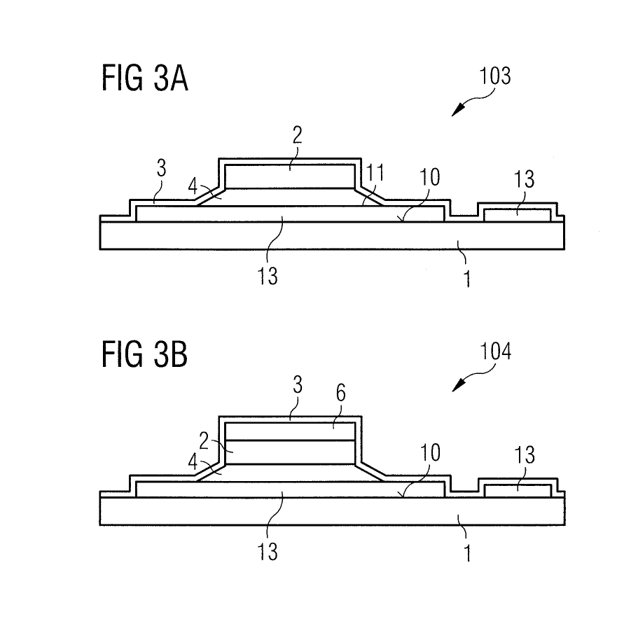

FIGS. 3A and 3B show further exemplary embodiments of light-emitting semiconductor components 103, 104 in accordance with further exemplary embodiments in each case in a sectional illustration.

In accordance with the exemplary embodiment in FIG. 3A, conductor tracks 13 in the form of metallizations are applied on a carrier 1, for example, a ceramic carrier, on the mounting area 10. A light-emitting semiconductor chip 2 is mounted and electrically connected by means of a connecting material 4 on a contact region 11 formed by a part of a conductor track. In this case, the connecting material 4 is formed by an electrically conductive sintering material. For this purpose, sinterable powder or granules, in particular silver-containing powder or granules, if appropriate comprising further sintering aids and/or binders, is or are applied on the conductor track 13 and the semiconductor chip 2 is applied thereon. The sintering material is sintered by the action of heat and/or by laser fusion, as a result of which a mechanical fixing of the semiconductor chip 2 on the conductor track 13 is produced which has a high thermal conductivity and good electrical conductivity. In this case, the sintering material is porous, the susceptibility of the porous structure to corrosion and moisture damage being prevented by virtue of the fact that the free surfaces of the semiconductor chip 2 and of the sintering material and of the conductor tracks 13 and also of the entire mounting area 10 are covered by an encapsulation layer 3 as described above.

In comparison with the exemplary embodiment in FIG. 3A, in the exemplary embodiment in FIG. 3B, a wavelength conversion element 6, for example, a ceramic lamina or a plastic element, for example, comprising a silicone-containing matrix material and a wavelength conversion substance embedded therein, is arranged on the semiconductor chip 2, said wavelength conversion element likewise being covered by the encapsulation layer 3. In particular, wavelength conversion substances used in conjunction with blue-emitting semiconductor chips 2 for generating white, in particular warm-white, light often have moisture instability. By encapsulating the conversion layer, or the wavelength conversion element 6, applied in proximity to the chip, it is possible to reduce the moisture sensitivity of the wavelength conversion substance. As an alternative thereto, a wavelength conversion substance can also be applied directly to the semiconductor chip 2 electrophoretically in order to form the wavelength conversion element 6.

Furthermore, an above-described protective layer and/or an optical element can also be applied on the encapsulation layer 3 of the semiconductor components 103 and/or 104.

The light-emitting semiconductor components shown in the exemplary embodiments can have further or alternative features described in the general part.

The invention is not restricted by the description on the basis of the exemplary embodiments. Rather, the invention encompasses any novel feature and any combination of features which in particular includes any combination of features in the patent claims, even if this feature or this combination of features itself is not explicitly specified in the patent claims or exemplary embodiments.

1-15. (canceled)

16. A method for producing a light-emitting semiconductor component, the method comprising:
locating a light-emitting semiconductor chip on a mounting area of a carrier, wherein the semiconductor chip is electrically connected to electrical contact regions on the mounting area; and
applying an encapsulation layer to the semiconductor chip by atomic layer deposition, wherein all surfaces of the semiconductor chip that are free and not covered by any material after mounting and electrical connection are covered with the encapsulation layer.

17. The method according to claim 16, wherein the encapsulation layer is applied at least to a part of the mounting area of the carrier.

18. The method according to claim 17, wherein the encapsulation layer is applied on the entire mounting area of the carrier.

19. The method according to claim 18, wherein the carrier electrical connection regions on the mounting area, the electrical connection regions for electrically connecting the semiconductor component, and the encapsulation layer is removed from the connection regions.

20. The method according to claim 16, wherein the semiconductor chip is connected to an electrical contact region by a wire connection and wherein the wire connection is covered by the encapsulation layer.

21. The method according to claim 16, wherein the semiconductor chip is connected to an electrical contact region by a connecting material comprising an electrically conductive sintering material.

22. The method according to claim 21, wherein the sintering material comprises silver.

23. The method according to claim 16, wherein a minor layer is arranged over the mounting area, the mirror layer being covered by the encapsulation layer.

24. The method according to claim 23, wherein the minor layer is applied to at least one part of a conductor track as a mounting area or forms at least one part of a conductor track.

25. The method according to claim 23, wherein the minor layer comprises silver.

26. The method according to claim 16, wherein, before the encapsulation layer is applied, the method further comprises forming a wavelength conversion element on the semiconductor chip, the wavelength conversion element being covered by the encapsulation layer.

27. A light-emitting semiconductor component, comprising:
a light-emitting semiconductor chip mounted on and electrically connected to a mounting area of a carrier by a connecting material formed by an electrically conductive sintering material;
and an encapsulation layer on the semiconductor chip, wherein the encapsulation layer covers all surfaces of the semiconductor chip that are free after the mounting and electrical connection of the semiconductor chip.

28. The light-emitting semiconductor component according to claim 27, wherein the carrier comprises a ceramic carrier.

29. The light-emitting semiconductor component according to claim 27, wherein the mounting area has connection regions and the mounting area and the semiconductor chip are covered with the encapsulation layer completely except for the connection regions.

30. The light-emitting semiconductor component according to claim 27, wherein the sintering material comprises silver.

31. The light-emitting semiconductor component according to claim 27,
wherein the semiconductor chip includes an electrode layer or an electrical contact structure on a side of the chip that faces away from the carrier, the electrode layer or electrical contact structure being connected to a contact resin on the mounting area of the carrier by a wire connection formed from a bond wire; and
wherein the bonding wire is covered by the encapsulation layer.

32. The light-emitting semiconductor component according to claim 27, further comprising a mirror layer arranged on at least one part of the mounting area, the mirror layer being covered by the encapsulation layer.

33. A method for producing a light-emitting semiconductor component, the method comprising:
arranging a light-emitting semiconductor chip on a mounting area of a carrier, wherein the semiconductor chip is electrically connected to electrical contact regions on the mounting area;
applying an encapsulation layer to the semiconductor chip by atomic layer deposition, wherein all surfaces of the semiconductor chip that are free and not covered by any material after mounting and electrical connection are covered with the encapsulation layer; and
forming a minor layer on at least one part of the mounting area, the mirror layer being covered by the encapsulation layer.
